(19) United States
(12) Patent Application Publication
(10) Pub. No.: US 2026/0312368 A1
(43) Pub. Date: Oct. 8, 2026

(54) LIGHT-EMITTING ELEMENT

(71) Applicant: SONY GROUP CORPORATION, TOKYO (JP)

(72) Inventors: YUICHIRO KIKUCHI, KANAGAWA (JP); TATSUSHI HAMAGUCHI, TOKYO (JP); EIJI NAKAYAMA, KANAGAWA (JP); RINTARO KODA, KANAGAWA (JP)

(21) Appl. No.: 19/482,796

(22) PCT Filed: Apr. 17, 2024
(86) PCT No.: PCT/JP2024/015243

§ 371 Date: Nov. 10, 2025

(30) Foreign Application Priority Data
May 22, 2023 (JP) 2023-084133

(51) Int. Cl. H01S 5/183; H01S 5/042

(52) U.S. Cl. CPC H01S 5/18361; H01S 5/0421

(57) ABSTRACT

The present disclosure provides a light-emitting element capable of increasing the conductivity of a conductive film while suppressing a decrease in light transmittance. [Solution] To solve the above problem, the present disclosure provides a light-emitting element including: a laminated structure that generates a laser light; and a conductive film that is laminated on the laminated structure, transmits the laser light, and has regions each with a defect density which is different.

### TECHNICAL FIELD

The present disclosure relates to a light-emitting element.

### BACKGROUND ART

In a light-emitting element composed of a surface-emitting laser element (VCSEL), laser oscillation typically occurs by causing laser light to resonate between two light reflection layers (Distributed Bragg Reflector layers, namely DBR layers). In such a light-emitting element, for example, a laminated structure is formed in which a first compound semiconductor layer, a light-emitting layer (active layer) composed of a compound semiconductor, and a second compound semiconductor layer are laminated. Thus, a second electrode composed of a conductive film that transmits light is formed on the second compound semiconductor layer, and a second light reflection layer composed of a thin-film laminated structure is formed on the second electrode. In order to enhance the light emission efficiency, it is required to enhance the conductivity of the conductive film.

### CITATION LIST

### Patent Document

Patent Document 1: WO 2018/083877 A

### SUMMARY OF THE INVENTION

### Problems to be Solved by the Invention

However, enhancing the conductivity of the conductive film may result in a decrease in light transmittance.

Therefore, the present disclosure provides a light-emitting element capable of enhancing the conductivity of the conductive film while suppressing a decrease in light transmittance.

### Solutions to Problems

To solve the above problem, the present disclosure provides
a light-emitting element including:
a laminated structure that generates a laser light; and
a conductive film that is laminated on the laminated structure, transmits the laser light, and has regions each with a defect density which is different.

The laminated structure may be formed by laminating a first compound semiconductor layer, a light-emitting layer, and a second compound semiconductor layer having a conductivity type different from a conductivity type of the first compound semiconductor layer, and the conductive film may be laminated on the first compound semiconductor layer or the second compound semiconductor layer.

The defect density refers to a density of at least one type of defects among point defects, line defects, planar defects, and volume defects, and the defects may be present either individually or in combination within the conductive film.

The conductive film may be made of at least one of indium tin oxide (ITO), indium titanium oxide (ITiO), Al2O3-ZnO (AZO), or InGaZnOx (IGZO).

The conductive film may be a current path during a driving operation for generating the laser light.

The laminated structure may be composed of a nitride semiconductor and may be configured as a vertical-cavity surface-emitting laser.

The conductive film may have a transmission region for the laser light and a first peripheral region different from the transmission region, and
the defect density may differ between the transmission region and the first peripheral region.

The defect density of the conductive film may differ depending on a distance in a direction along the laminated structure from a predetermined point within the transmission region.

The light-emitting element according to (7), wherein the first peripheral region is electrically connected to an electrode which supplies current.

The light-emitting element may further include:
a first light reflection layer that is formed on a side of a first surface of the laminated structure; and
a second light reflection layer that is formed on a side of a second surface facing the first surface.

The first light reflection layer may include a concave mirror portion.

On a surface of the conductive film facing the concave mirror portion, the defect density may differ between a region where light is concentrated by the concave mirror portion and a peripheral region.

On a surface facing the concave mirror portion, the defect density may differ between a region where light is concentrated by the concave mirror portion and a peripheral region.

The defect density may increase from an optical axis of the concave mirror portion toward a peripheral portion.

The light-emitting element may further include a nitride layer laminated between the second light reflection layer and the conductive film.

The conductive film may have the transmission region, and a second peripheral region located between the transmission region and the first peripheral region, and the defect density may differ among the transmission region, the first peripheral region, and the second peripheral region.

The defect density of the transmission region may be configured to be lower than the defect density of the first peripheral region.

The defect density of the second peripheral region may be configured to be lower than the defect density of the transmission region and the defect density of the first peripheral region.

The second peripheral region may correspond to a current injection limiting region.

To solve the above problem, the present disclosure provides
a light-emitting element including:
a laminated structure that generates a laser light;
a first light reflection layer that is formed on a side of a first surface of the laminated structure;
a second light reflection layer that is formed on a side of
a second surface facing the first surface;
a conductive film that is laminated on the laminated structure and transmits the laser light; and
a nitride layer that is laminated between the second light reflection layer and the conductive film.

### BRIEF DESCRIPTION OF DRAWINGS

FIG. 1 is a schematic plan view illustrating an example of a light-emitting element according to an embodiment of the present disclosure.

FIG. 2 is an AA cross-sectional view of FIG. 1.

FIG. 3 is a diagram illustrating a current non-injection region in the light-emitting element of FIG. 2.

FIG. 4 is a BB cross-sectional view of FIG. 1.

FIG. 5 is a diagram schematically illustrating a distribution of defects in a conductive film.

FIG. 6 is a diagram schematically illustrating a change in a grain boundary size of the conductive film.

FIG. 7 is an enlarged view of a light-emitting region.

FIG. 8 is a CC cross-sectional view of FIG. 7.

FIG. 9 is a diagram schematically illustrating light distribution in the AA cross-sectional view of FIG. 1.

FIG. 10 is a diagram schematically illustrating a transition of oxygen toward a metal side in the AA cross-sectional view of FIG. 1.

FIG. 11 is a diagram schematically illustrating how stress is applied to the conductive film in the AA cross-sectional view of FIG. 1.

FIG. 12 is a diagram schematically illustrating a light-emitting element further including a silicon nitride film.

FIG. 13 is the AA cross-sectional view of FIG. 1, schematically illustrating a light-emitting element according to Modification 1 of a seventh embodiment.

### MODE FOR CARRYING OUT THE INVENTION

Hereinafter, embodiments of a light-emitting element will be described with reference to the drawings. Although main components of the light-emitting element will be mainly described below, the light-emitting element can include components and functions that are not illustrated or described. The following description is not intended to exclude component parts and functions that are not illustrated or described.

### First Embodiment

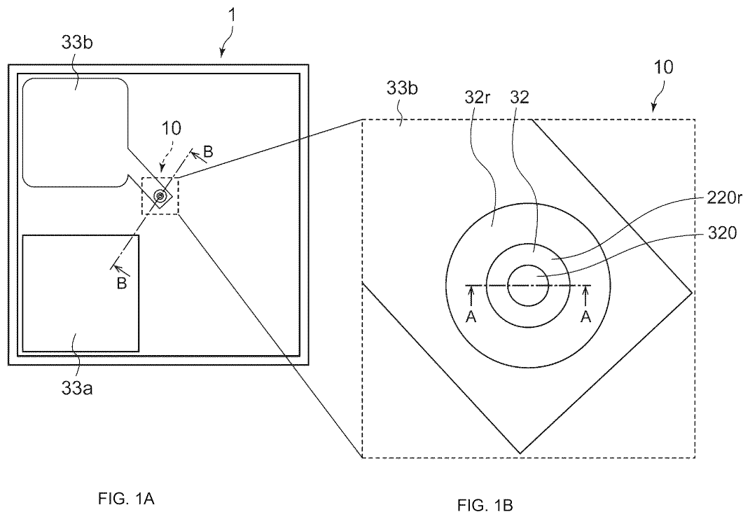

FIG. 1 is a schematic plan view illustrating an example of a light-emitting element 1 according to an embodiment of the present disclosure. FIG. 1(a) is a plan view of the entire light-emitting element 1, and FIG. 1(b) is an enlarged view of a light-emitting region 10. Moreover, in the present embodiment, a semiconductor laser element including a surface-emitting laser element may be referred to as “light-emitting element”.

As illustrated in FIG. 1(a), the light-emitting element 1 includes a first pad electrode 33a and a second pad electrode 33b for electrically connecting to an external electrode or circuit. The pad electrodes 33a and 33b may have a single-layer configuration or a multilayer configuration containing at least one metal selected from a group consisting of titanium (Ti), aluminum (Al), platinum (Pt), gold (Au), nickel (Ni), and palladium (Pd), for example. Alternatively, the pad electrodes 33a and 33b may have a multilayer configuration exemplified by a Ti/Pt/Au multilayer configuration, a Ti/Au multilayer configuration, a Ti/Pd/Au multilayer configuration, a Ti/Ni/Au multilayer configuration, or a Ti/Ni/Au/Cr/Au multilayer configuration.

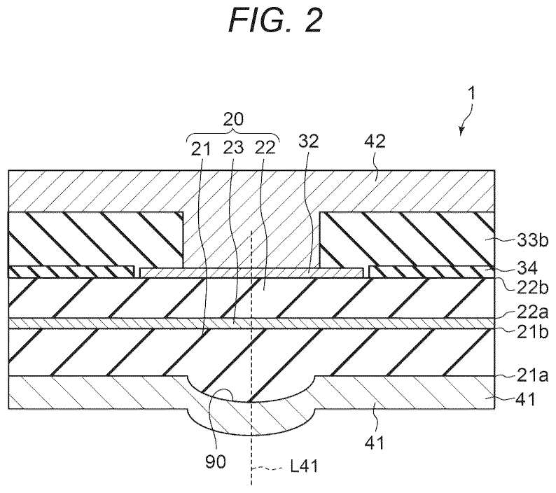

As illustrated in FIG. 1(b), the second pad electrode 33b is electrically connected to a first peripheral region 32r of a conductive film 32 that transmits light. As a result, a current supplied via the first pad electrode 33a and the second pad electrode 33b is supplied to a light-emitting layer (active layer) 23 (see FIG. 2 described later) via the conductive film 32 that transmits light. Moreover, in the present embodiment, the conductive film 32 that transmits light may be referred to as second electrode 32 or simply as conductive film 32.

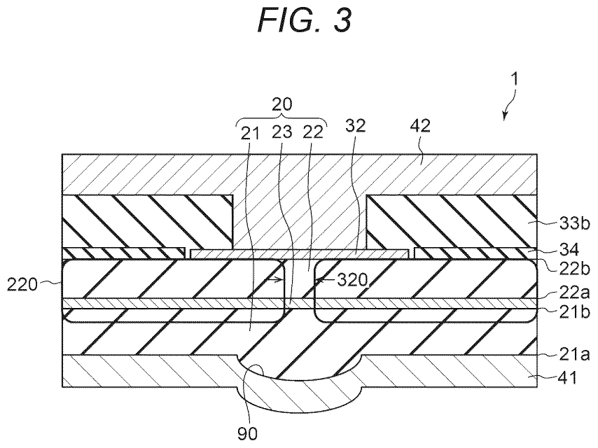

The second pad electrode 33b is electrically connected to the first peripheral region 32r of the conductive film 32. Around a current injection region 320 of the conductive film 32, a second peripheral region 220r corresponding to a current non-injection region (implant region) 220 (see FIG. 3), which restricts a current conduction range, is configured. The second peripheral region 220r and the current injection region 320 are light transmission regions. Moreover, although the present embodiment includes the current non-injection region 220, the present embodiment is not limited thereto. For example, the light-emitting element 1 may be configured without including the current non-injection region 220.

Light emitted from the light-emitting layer 23 (see FIG. 2 described later) resonates and produces laser emission. In the present embodiment, the laser light is focused toward the center of the current injection region 320. Moreover, the current injection region 320 and the first peripheral region 32r are not limited to circular shapes and may instead be polygonal, such as pentagonal or quadrilateral, or elliptical. Additionally, although in the present embodiment, the laser light is focused toward the center of the current injection region 320, the laser light is not limited thereto. For example, the light-emitting element 1 may be configured such that the laser light is not focused toward the center of the current injection region 320.

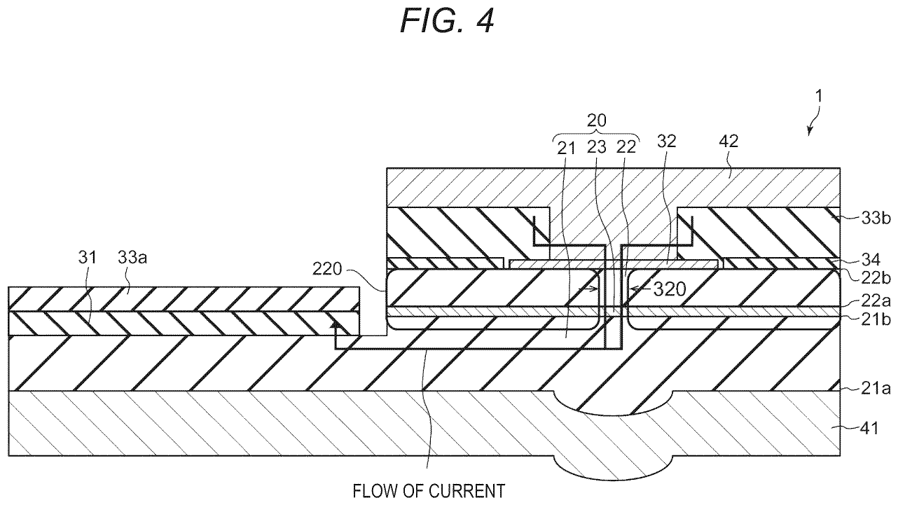

Here, a configuration example of the light-emitting element 1 will be described with reference to FIGS. 2 to 4. FIG. 2 is an AA cross-sectional view of FIG. 1. FIG. 3 is a diagram illustrating the current non-injection region 220 in the light-emitting element 1 of FIG. 2. FIG. 4 is a BB cross-sectional view of FIG. 1. As illustrated in FIGS. 2 to 4, the light-emitting element 1 has a laminated configuration in which a first light reflection layer 41, a laminated structure 20, and a second light reflection layer 42 are laminated. Thus, the laminated structure 20 is configured by laminating a first compound semiconductor layer 21, the light-emitting layer (active layer) 23, and a second compound semiconductor layer 22 in this order from the first light reflection layer 41 side.

Light emitted from the laminated structure 20 is emitted to the outside via either the first light reflection layer 41 or the second light reflection layer 42. In the present embodiment, the light is emitted to the outside via the second light reflection layer 42. Additionally, the first light reflection layer 41 has a structure in which at least two types of thin films are alternately laminated in a plurality of layers. Similarly, the second light reflection layer 42 also has a structure in which at least two types of thin films are alternately laminated in a plurality of layers. Moreover, in the light-emitting element 1 according to the present embodiment, light from the laminated structure 20 is emitted to the outside via the second light reflection layer 42, however, the light-emitting element 1 is not limited thereto. For example, the first light reflection layer 41 may have a flat shape, and the light may be emitted to the outside via the first light reflection layer 41.

More specifically, the first compound semiconductor layer 21 has a first surface 21a and a second surface 21b facing the first surface 21a, with the thickness of its planar portion which has a first conductivity type (specifically, n-type) being, for example, several tens of micrometers. The first light reflection layer 41 is formed on the first surface 21a. The second surface 21b has a flat shape. On the other hand, the first compound semiconductor layer 21 and the first light reflection layer 41 each have a convex portion with respect to the second surface 21b. This convex portion forms a concave mirror portion 90 on the side of the second compound semiconductor layer 22. An optical axis L41 of the concave mirror portion 90 passes, for example, through the center point of the current injection region 320 (see FIG. 1). Moreover, although the light-emitting element 1 according to the present embodiment includes the convex portion, the light-emitting element 1 is not limited thereto. For example, the first surface 21a of the first compound semiconductor layer 21 may have a flat shape. Similarly, the shape on the first surface 21a side of the first light reflection layer 41 may also be flat.

The second compound semiconductor layer 22 has a second conductivity type (specifically, p-type) and has a thickness of, for example, several tens of nanometers. The light-emitting layer (active layer) 23 faces the second surface 21b of the first compound semiconductor layer 21. The thickness of the first compound semiconductor layer 21 is greater than the thickness of the second compound semiconductor layer 22. For example, the first compound semiconductor layer 21 is composed of an n-GaN layer; the light-emitting layer (active layer) 23 is composed of a multiple quantum well structure in which an InₓGa₍₁₋ₓN layer (barrier layer) and an In_{y}Ga_{(1-y)}N layer (well layer) are laminated; and the second compound semiconductor layer 22 is composed of a p-GaN layer.

Thus, a resonator includes a region of the first light reflection layer 41 extending from the first surface 21a of the first compound semiconductor layer 21 to a certain depth, the laminated structure 20 (the first compound semiconductor layer 21, the light-emitting layer 23, and the second compound semiconductor layer 22), and a region of the second light reflection layer 42 extending from the second surface 22b of the second compound semiconductor layer 22 to a certain depth. As described above, light emitted from the light-emitting layer 23 resonates within the resonator and produces laser emission. In this case, the laser light is focused toward the optical axis L41 by the concave mirror portion 90 and transmits through the second peripheral region 220r and the current injection region 320 (see FIG. 1).

The first electrode 31 (see FIG. 4) is formed on the second surface 21b of the first compound semiconductor layer 21. The first electrode 31 is composed of, for example, Ti/Pt/Au. On the first electrode 31, the first pad electrode 33a (see FIG. 4) is formed or connected for electrical connection to an external electrode or circuit. On the other hand, the conductive film (second electrode) 32 is formed on the second compound semiconductor layer 22, and the second light reflection layer 42 is formed on the conductive film 32.

The second light reflection layer 42 on the conductive film 32, which is the second electrode, has a flat shape. The conductive film 32 is composed of a transparent conductive material, specifically, ITO. That is, the conductive film 32 is composed of indium tin oxide (ITO), indium titanium oxide (ITiO), Al2O3-ZnO (AZO), or InGaZnox (IGZO). As described above, the second pad electrode 33b for electrical connection to an external electrode or circuit is formed or connected on the peripheral region 32r of the conductive film 32.

An insulating layer (current constriction layer) 34 is composed of, for example, SiO₂. The insulating layer 34, which has an opening, defines a current constriction region.

As illustrated in FIGS. 3 and 4, in order to further control a current path (current injection region) through which current flows between the first electrode 31 and the conductive film (second electrode) 32, the current non-injection region (implant region) 220 is formed to surround the current injection region 320.

In a GaAs-based surface-emitting laser element (a surface-emitting laser element composed of a GaAs-based compound semiconductor), the current non-injection region 220 that surrounds the current injection region 320 can be formed as an implant region by oxidizing the light-emitting layer from the outside along an XY plane.

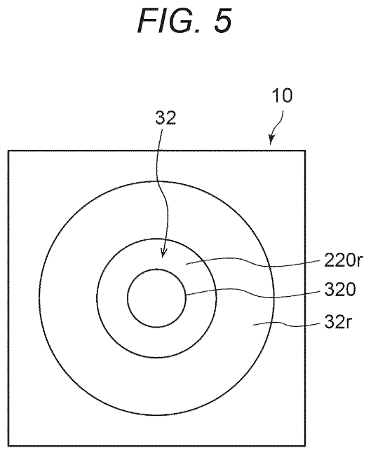

FIG. 5 is a diagram schematically illustrating a distribution of defects in the conductive film 32. As illustrated in FIG. 5, the diagram schematically illustrates the distribution of defects in the conductive film 32. In the conductive film 32 according to the present embodiment, the defect density of the conductive film 32 differs in the normal direction from the center of the current injection portion 320 toward the periphery. For example, the defect density in the first peripheral region 32r, which is electrically connected to the second pad electrode 33b, is made higher than that in the current injection portion 320 through which light transmits and the second peripheral region 220r. In other words, the number of defects in the first peripheral region 32r is made greater than the number of defects in the current injection portion 320 and the second peripheral region 220r. Moreover, in the conductive film 32 of the present embodiment, defect refers to point defect, line defect, planar defect, or volume defect. Additionally, a state in which any of these defects exist either individually or in combination is also referred to as defect.

The conductive film 32, such as ITO, exhibits variations in light absorption and electrical resistance depending on the number of defects. A reduction in defects tends to decrease light absorption but increase electrical resistance. Conversely, an increase in defects tends to increase light absorption but decrease electrical resistance.

As understood from the above, by reducing the number of defects in the current injection portion 320, through which light transmits, and in the second peripheral region 220r, while increasing the number of defects in the first peripheral region 32r that is electrically connected to the second pad electrode 33b, both light absorption and electrical resistance can be decreased.

Additionally, it is also possible to change the number of defects in each of the current injection portion 320, the second peripheral region 220r, and the first peripheral region 32r. For example, the number of defects may be increased in order from the current injection portion 320 to the second peripheral region 220r, and then to the first peripheral region 32r. As a result, electrical conductivity increases from the center of the current injection portion 320 toward the peripheral portion. On the other hand, light transmittance increases from the peripheral portion of the conductive film 32 toward the center of the current injection portion 320.

Furthermore, the defect density in the second peripheral region 220r may be enhanced to the highest level. In the first peripheral region 32r, a main current may flow on the side of the second pad electrode 33b. In this case, a larger amount of current may flow through the second peripheral region 220r than through the first peripheral region 32r of the conductive film 32. As a result, electrical conductivity increases from the center of the current injection portion 320 toward the second peripheral region 220r. On the other hand, light transmittance increases from the second peripheral region 220r of the conductive film 32 toward the center of the current injection portion 320.

Additionally, the number of defects may also be increased in accordance with the distance from the center of the current injection portion 320 toward the peripheral portion. In other words, the center of the current injection portion 320 has the lowest defect density, while the peripheral portion has the highest defect density. In this case as well, electrical conductivity increases from the center of the current injection portion 320 toward the peripheral portion, and light transmittance increases from the peripheral portion of the conductive film 32 toward the center of the current injection portion 320.

As described above, the conductive film 32 of the light-emitting element 1 according to the present embodiment is configured to have regions with different defect densities. This makes it possible to change the defect density according to the characteristics of electrical conductivity and light transmittance, thereby enabling both the light absorption and the electrical resistance of the conductive film 32 to be reduced.

### Second Embodiment

In the light-emitting element 1 according to the second embodiment, the conductive film 32 differs from that of the light-emitting element 1 according to the first embodiment in that a grain boundary size is changed from the peripheral portion toward the center of the current injection portion 320. Hereinafter, differences from the light-emitting element 1 according to the first embodiment will be described.

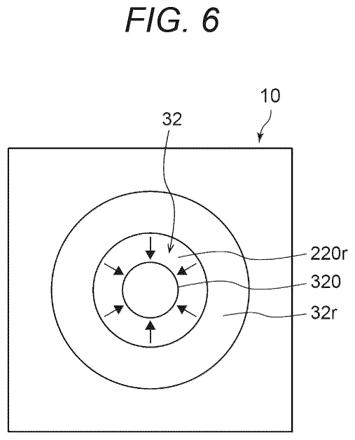

FIG. 6 is a diagram schematically illustrating a change in the grain boundary size of the conductive film 32. The arrows schematically indicate the direction in which the grain boundary size increases. As illustrated in FIG. 6, in the conductive film 32 according to the present embodiment, the grain boundary size is configured to increase from the peripheral portion toward the center of the current injection portion 320. For example, the grain boundary size in the current injection portion 320 is configured to be larger than that in the second peripheral region 220r.

The conductive film 32, such as ITO, exhibits variations in light absorption and electrical resistance depending on the grain boundary size. Increasing the grain boundary size tends to decrease light absorption but increase electrical resistance.

Conversely, decreasing the grain boundary size tends to increase light absorption but decrease electrical resistance. As understood from the above, by configuring the grain boundary size to increase from the peripheral portion toward the center of the current injection portion 320, it is possible to enhance light transmittance from the peripheral portion of the conductive film 32 toward the center of the current injection portion 320. Furthermore, it is possible to enhance electrical conductivity from the center of the current injection portion 320 toward the peripheral portion.

### Modification 1 of Second Embodiment

The light-emitting element 1 according to Modification 1 of the second embodiment differs from the light-emitting element 1 according to the second embodiment in that the second pad electrode 33b, which is electrically connected to the conductive film 32, has a ring-shaped structure. Hereinafter, differences from the light-emitting element 1 according to the second embodiment will be described.

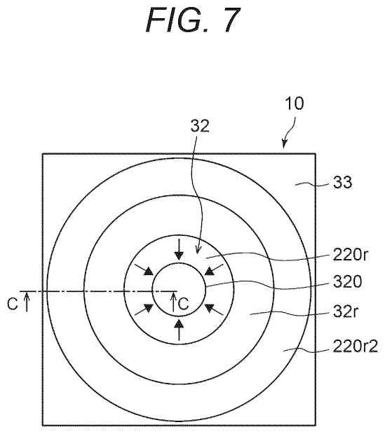

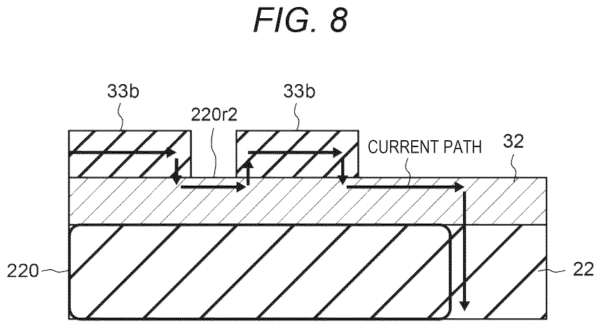

FIG. 7 is an enlarged view of the light-emitting region 10. FIG. 8 is a CC cross-sectional view of FIG. 7. As illustrated in FIGS. 7 and 8, in the light-emitting element 1 according to Modification 1 of the second embodiment, the second pad electrode 33b is electrically connected to the conductive film 32 in a ring shape.

As illustrated in FIG. 8, in regions where the second pad electrode 33b is electrically connected, the current supplied from the second pad electrode 33b mainly flows on the side of the second pad electrode 33b rather than on the side of the conductive film 32. On the other hand, in regions where the second pad electrode 33b is not electrically connected, the current supplied from the second pad electrode 33b flows on the side of the conductive film 32.

As illustrated in FIG. 7, in the conductive film 32 according to the present embodiment, the grain boundary size is configured to increase from the peripheral portion toward the center of the current injection portion 320. For example, the grain boundary size in the current injection portion 320 is configured to be larger than that in the second peripheral region 220r. A third peripheral region 220r2 is a side on which light does not transmit and current flows. Therefore, the grain boundary size in the third peripheral region 220r2 of the conductive film 32 is configured to be smaller than that in the current injection portion 320. As a result, in addition to the effects of the light-emitting element 1 according to the second embodiment, the electrical conductivity in the third peripheral region 220r2, which is a region where the second pad electrode 33b is not electrically connected, can be enhanced. Thus, by changing the grain boundary size of the conductive film 32 between regions where the second pad electrode 33b is electrically connected and regions where the second pad electrode 33b is not electrically connected, it is possible to enhance light transmittance while maintaining electrical conductivity.

### Third Embodiment

In the light-emitting element 1 according to the third embodiment, the conductive film 32 differs from that of the light-emitting element 1 according to the first embodiment in that the defect density is changed according to the intensity distribution of the laser light. Hereinafter, differences from the light-emitting element 1 according to the first embodiment will be described.

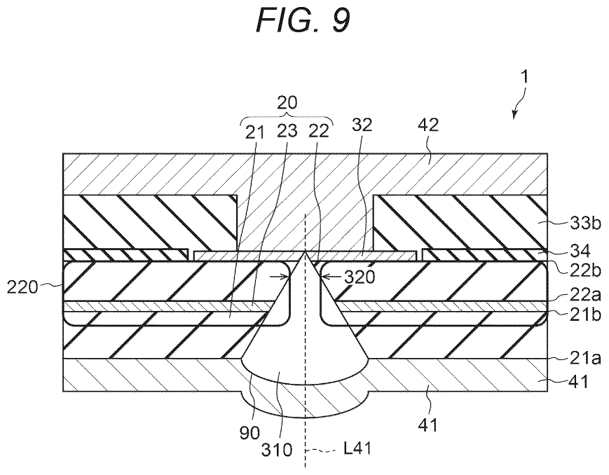

FIG. 9 is a diagram schematically illustrating light distribution of a laser light 310 in the AA cross-sectional view of FIG. 1. In the light-emitting element 1 according to the third embodiment, the defect density of the conductive film 32 is changed in accordance with the intensity of the light distribution of the laser light 310. That is, the defect density is made lower in regions where the intensity of the light distribution of the laser light 310 is higher. More specifically, the defect density is decreased progressively from the periphery toward the point through which the optical axis L41 of the concave mirror portion 90 passes. In other words, the defect density is increased progressively from the point through which the optical axis L41 of the concave mirror portion 90 passes toward the periphery.

Thus, the distribution of defects in the conductive film 32 may be controlled such that the defect density is decreased in a region facing the concave mirror portion 90 of the first light reflection layer 41, where light is concentrated, and increased in a peripheral region. That is, the defect density in a region of the conductive film 32 where the light intensity distribution is high may be further decreased, while the defect density in a region of the conductive film 32 where the light intensity distribution is low may be further increased. As is apparent from the above, by correlating the light intensity distribution of the conductive film 32 with the defect density, it is possible to suppress light absorption within the current injection portion 320 and suppress an increase in electrical resistance in the first peripheral region 32r, where the second pad electrode 33b is electrically connected.

As illustrated in FIG. 9, the current non-injection region 220, which corresponds to an oxidized region 33 of the light-emitting layer, has a lower refractive index compared to a non-oxidized region (current injection region). As a result, the optical path length of the resonator (expressed as the product of the refractive index and the physical distance) is shorter in the current non-injection region than in the current injection region. Thus, a kind of “lens effect” occurs together with the focusing power of the concave mirror portion 90, thereby confining the laser light 310 toward the center of the surface-emitting laser element in a direction along the optical axis L41. In general, light tends to spread due to diffraction effects, and thus, laser light reciprocating within the resonator gradually dissipates outside the resonator (diffraction loss), causing adverse effects such as an increase in threshold current. However, since the lens effect and the focusing by the concave mirror portion 90 compensate for this diffraction loss, it is possible to suppress an increase in the threshold current and other adverse effects.

As understood from the above, by reducing the number of defects in the current injection portion 320 located at the central portion of the element where light is concentrated, and increasing the number of defects in the second peripheral region 220r and the first peripheral region 32r located at the outer periphery, both light absorption and electrical resistance can be reduced. Thus, it is possible to suppress adverse effects such as an increase in threshold current while simultaneously reducing both light absorption and electrical resistance.

### Fourth Embodiment

The conductive film 32 of the light-emitting element 1 according to the fourth embodiment differs from that of the light-emitting element 1 according to the first embodiment in that the phenomenon in which oxygen in the conductive film 32 migrates toward the second pad electrode 33b is also utilized. Hereinafter, differences from the light-emitting element 1 according to the first embodiment will be described.

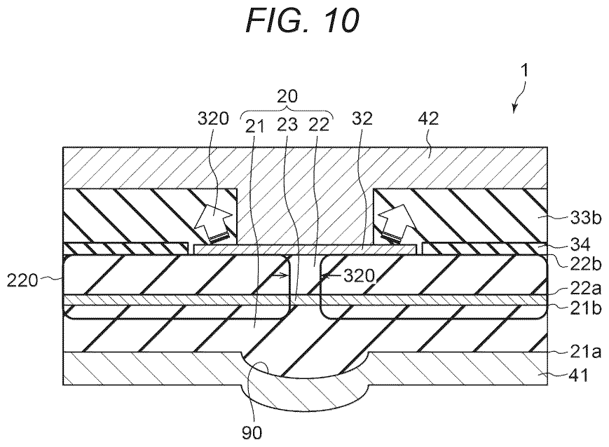

FIG. 10 is a diagram schematically illustrating a transition of oxygen toward a metal side in the AA cross-sectional view of FIG. 1. The arrows 320 schematically indicate the direction of oxygen migration.

As illustrated in FIG. 10, oxygen in the conductive film 32 that is in contact with the second pad electrode 33b made of a metal material migrates toward the second pad electrode 33b. As a result, oxygen vacancies are formed in the region where the oxygen in the conductive film 32 has migrated, thereby decreasing electrical resistance. Thus, by configuring the conductive film 32 and the second pad electrode 33b made of the metal material in the peripheral portions of the current injection portion 320 and the second peripheral portion 220r, which are light transmission regions, it is possible to increase the oxygen vacancy density while suppressing a decrease in light absorption, thereby further decreasing electrical resistance.

### Fifth Embodiment

The conductive film 32 of the light-emitting element 1 according to the fifth embodiment differs from the conductive film 32 of the light-emitting element 1 according to the first embodiment in that the stress of the conductive film 32 is also utilized. Hereinafter, differences from the light-emitting element 1 according to the first embodiment will be described.

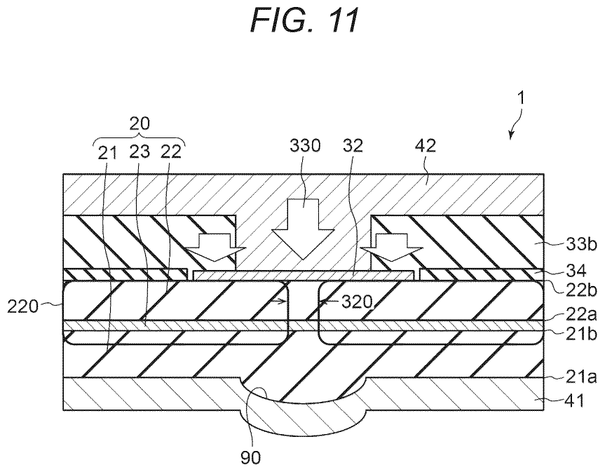

FIG. 11 is a diagram schematically illustrating how stress is applied to the conductive film 32 in the AA cross-sectional view of FIG. 1. The arrows 330 schematically indicate the direction and magnitude of the stress.

As illustrated in FIG. 11, the stress 330 of the second light reflection layer 42 applied to the current injection portion 320 of the conductive film 32 is greater than the stress 330 of the second light reflection layer 42 applied to the first peripheral region 32r. As a result, the defect density generation rate differs between the current injection portion 320 and the first peripheral region 32r. Thus, by configuring the stress 330 of the second light reflection layer 42 to be applied more strongly to the current injection portion 320, which is a light transmission region, it is possible to further decrease electrical resistance while suppressing a decrease in light absorption.

### Sixth Embodiment

The light-emitting element 1 according to the sixth embodiment differs from the light-emitting elements 1 according to the fourth and fifth embodiments in that a silicon nitride film (SiN) is configured on the surface of the second light reflection layer 42 opposite to the emission side. Hereinafter, differences from the light-emitting element 1 according to the fourth and fifth embodiments will be described.

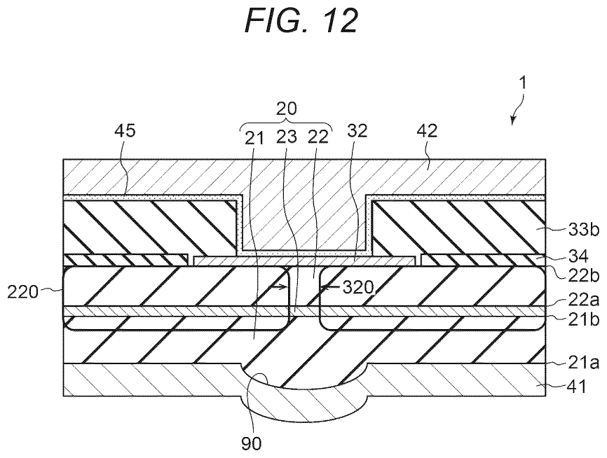

FIG. 12 is a diagram schematically illustrating the light-emitting element 1 further including a silicon nitride film (SiN) 45 in the AA cross-sectional view of FIG. 1. The arrows 320 schematically indicate the direction of oxygen migration. As illustrated in FIG. 12, by configuring the silicon nitride film 45 on the surface of the second light reflection layer 42 opposite to the emission side, it is possible, in addition to the effects of the light-emitting element 1 according to the fifth embodiment, to suppress oxygen migration from the current injection portion 320 and the second peripheral region 220r, which are light transmission regions of the conductive film 32.

Additionally, by adjusting the film thickness of the silicon nitride film 45 in regions covering the current injection portion 320 and the second peripheral region 220r, it is possible to adjust the magnitude of the stress 330 (see FIG. 11). As a result, in addition to the effects of the light-emitting element 1 according to the sixth embodiment, it is possible to control the balance of the stress 330 (see FIG. 11) applied to the current injection portion 320 and the second peripheral region 220r, which are light transmission regions of the conductive film 32.

### Modification 1 of Sixth Embodiment

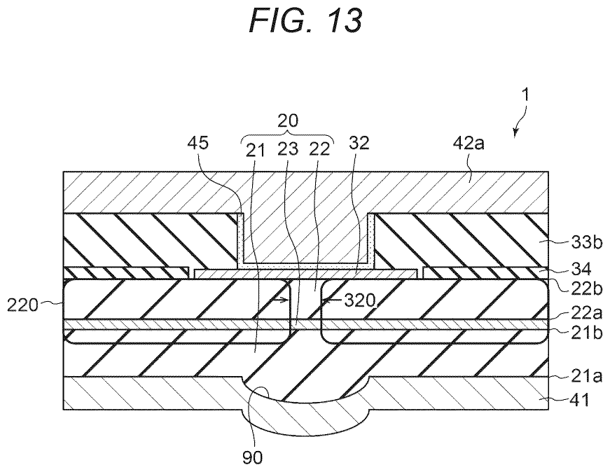

FIG. 13 is the AA cross-sectional view of FIG. 1, schematically illustrating the light-emitting element 1 according to Modification 1 of the sixth embodiment. As illustrated in FIG. 13, the silicon nitride film (SiN) 45 may be configured to cover only the current injection portion 320 and the second peripheral region 220r, which are laser light transmission regions. This allows the characteristics of the laser light transmission regions and the characteristics of other regions in the conductive film 32 to be changed.

Moreover, the present technology may have the following configurations.

(1)

A light-emitting element including:
a laminated structure that generates a laser light; and
a conductive film that is laminated on the laminated structure, transmits the laser light, and has regions each with a defect density which is different.
(2) The light-emitting element according to (1), wherein
the laminated structure is formed by laminating a first compound semiconductor layer, a light-emitting layer, and a second compound semiconductor layer having a conductivity type different from a conductivity type of the first compound semiconductor layer, and
the conductive film is laminated on the first compound semiconductor layer or the second compound semiconductor layer.
(3) The light-emitting element according to (1), wherein the defect density refers to a density of at least one type of defects among point defects, line defects, planar defects, and volume defects, and the defects are present either individually or in combination within the conductive film.
(4) The light-emitting element according to (1), wherein the conductive film is made of at least one of indium tin oxide (ITO), indium titanium oxide (ITiO), Al2O3-ZnO (AZO), or InGaZnOx (IGZO).
(5) The light-emitting element according to (1), wherein the conductive film is a current path during a driving operation for generating the laser light.
(6) The light-emitting element according to (1), wherein the laminated structure is composed of a nitride semiconductor and is configured as a vertical-cavity surface-emitting laser.
(7) The light-emitting element according to (1), wherein
the conductive film has a transmission region for the laser light and a first peripheral region different from the transmission region, and
the defect density differs between the transmission region and the first peripheral region.
(8) The light-emitting element according to (7), wherein the defect density of the conductive film differs depending on a distance in a direction along the laminated structure from a predetermined point within the transmission region.
(9) The light-emitting element according to (7), wherein the first peripheral region is electrically connected to an electrode which supplies current.
(10) The light-emitting element according to (1), further including:
a first light reflection layer that is formed on a side of a first surface of the laminated structure; and
a second light reflection layer that is formed on a side of a second surface facing the first surface.
(11) The light-emitting element according to (10), wherein the first light reflection layer includes a concave mirror portion.
(12) The light-emitting element according to (11), wherein on a surface of the conductive film facing the concave mirror portion, the defect density differs between a region where light is concentrated by the concave mirror portion and a peripheral region.
(13) The light-emitting element according to (11), wherein on a surface facing the concave mirror portion, the defect density differs between a region where light is concentrated by the concave mirror portion and a peripheral region.
(14) The light-emitting element according to (11), wherein the defect density increases from an optical axis of the concave mirror portion toward a peripheral portion.
(15) The light-emitting element according to (10 further including
a nitride layer laminated between the second light reflection layer and the conductive film.
(16) The light-emitting element according to (7), wherein
the conductive film has the transmission region, and a second peripheral region located between the transmission region and the first peripheral region, and
the defect density differs among the transmission region, the first peripheral region, and the second peripheral region.
(17) The light-emitting element according to (7), wherein the defect density of the transmission region is configured to be lower than the defect density of the first peripheral region.
(18) The light-emitting element according to (16), wherein the defect density of the second peripheral region is configured to be lower than the defect density of the transmission region and the defect density of the first peripheral region.
(19) The light-emitting element according to (18), wherein the second peripheral region corresponds to a current injection limiting region.
(20) A light-emitting element including:
a laminated structure that generates a laser light;
a first light reflection layer that is formed on a side of a first surface of the laminated structure;
a second light reflection layer that is formed on a side of
a second surface facing the first surface;
a conductive film that is laminated on the laminated structure and transmits the laser light; and
a nitride layer that is laminated between the second light reflection layer and the conductive film.

Aspects of the present disclosure are not limited to the above-described individual embodiments, but include various modifications that can be conceived by those skilled in the art, and the effects of the present disclosure are not limited to the above-described contents. In other words, various additions, modifications, and partial deletions may be made without departing from the conceptual idea and spirit of the present disclosure derived from the matters defined in the claims and equivalents thereof.

### REFERENCE SIGNS LIST

1 Light-emitting element
20 Laminated structure
21 First compound semiconductor layer
22 Second compound semiconductor layer
23 Light-emitting layer (active layer)
32r First peripheral region
33b Second pad electrode
41 First light reflection layer
42 Second light reflection layer
90 Concave mirror portion
220 Current non-injection region
220r Second peripheral region
320 Current injection region
L41 Optical axis

1. A light-emitting element comprising:
a laminated structure that generates a laser light; and
a conductive film that is laminated on the laminated structure, transmits the laser light, and has regions each with a defect density which is different.

2. The light-emitting element according to claim 1, wherein
the laminated structure is formed by laminating a first compound semiconductor layer, a light-emitting layer, and a second compound semiconductor layer having a conductivity type different from a conductivity type of the first compound semiconductor layer, and
the conductive film is laminated on the first compound semiconductor layer or the second compound semiconductor layer.

3. The light-emitting element according to claim 1, wherein the defect density refers to a density of at least one type of defects among point defects, line defects, planar defects, and volume defects, and the defects are present either individually or in combination within the conductive film.

4. The light-emitting element according to claim 1, wherein the conductive film is made of at least one of indium tin oxide (ITO), indium titanium oxide (ITiO), Al2O3-Zno (AZO), or InGaZnOx (IGZO).

5. The light-emitting element according to claim 1, wherein the conductive film is a current path during a driving operation for generating the laser light.

6. The light-emitting element according to claim 1, wherein the laminated structure is composed of a nitride semiconductor and is configured as a vertical-cavity surface-emitting laser.

7. The light-emitting element according to claim 1, wherein
the conductive film has a transmission region for the laser light and a first peripheral region different from the transmission region, and
the defect density differs between the transmission region and the first peripheral region.

8. The light-emitting element according to claim 7, wherein the defect density of the conductive film differs depending on a distance in a direction along the laminated structure from a predetermined point within the transmission region.

9. The light-emitting element according to claim 7, wherein the first peripheral region is electrically connected to an electrode which supplies current.

10. The light-emitting element according to claim 1, further comprising:
a first light reflection layer that is formed on a side of a first surface of the laminated structure; and
a second light reflection layer that is formed on a side of a second surface facing the first surface.

11. The light-emitting element according to claim 10, wherein the first light reflection layer includes a concave mirror portion.

12. The light-emitting element according to claim 11, wherein on a surface of the conductive film facing the concave mirror portion, the defect density differs between a region where light is concentrated by the concave mirror portion and a peripheral region.

13. The light-emitting element according to claim 11, wherein on a surface facing the concave mirror portion, the defect density differs between a region where light is concentrated by the concave mirror portion and a peripheral region.

14. The light-emitting element according to claim 11, wherein the defect density increases from an optical axis of the concave mirror portion toward a peripheral portion.

15. The light-emitting element according to claim 10 further comprising
a nitride layer laminated between the second light reflection layer and the conductive film.

16. The light-emitting element according to claim 7, wherein
the conductive film has the transmission region, and a second peripheral region located between the transmission region and the first peripheral region, and
the defect density differs among the transmission region, the first peripheral region, and the second peripheral region.

17. The light-emitting element according to claim 7, wherein the defect density of the transmission region is configured to be lower than the defect density of the first peripheral region.

18. The light-emitting element according to claim 16, wherein the defect density of the second peripheral region is configured to be lower than the defect density of the transmission region and the defect density of the first peripheral region.

19. The light-emitting element according to claim 18, wherein the second peripheral region corresponds to a current injection limiting region.

20. A light-emitting element comprising:
a laminated structure that generates a laser light;
a first light reflection layer that is formed on a side of a first surface of the laminated structure;
a second light reflection layer that is formed on a side of a second surface facing the first surface;
a conductive film that is laminated on the laminated structure and transmits the laser light; and
a nitride layer that is laminated between the second light reflection layer and the conductive film.
